(19) United States
(12) Patent Application Publication
(10) Pub. No.: US 2014/0339673 A1
(43) Pub. Date: Nov. 20, 2014

(54) WAFER PROCESSING

(71) Applicant: Texas Instruments Incorporated, Dallas, TX (US)

(72) Inventors: Iriguchi Shoichi, Beppu-city (JP); Aoya Kengo, III, Beppu-city (JP); Yano Genki, Beppu-city (JP); Hayata Kazunori, Beppu-city (JP)

(73) Assignee: Texas Instruments Incorporated, Dallas, TX (US)

(21) Appl. No.: 13/894,191

(22) Filed: May 14, 2013

(51) Int. Cl. H01L 21/78; H01L 27/02

(52) U.S. Cl. CPC H01L 21/78; H01L 27/0203
USPC 257/499; 438/464

(57) ABSTRACT

A method of separating dies of a singulated wafer is disclosed. The method may include supporting the singulated wafer on a supporting portion of a sheet of dicing tape that has a first ring attached to a first annular portion of the sheet that encompasses the supporting portion. The method may further include radially expanding the supporting portion by relative axial displacement of the supporting portion with respect to the first ring. The method may also include further expanding the supporting portion by radially outward displacement of a support surface that supports at least an annular portion of the sheet. The method may also include attaching a second ring to a second annular portion of the sheet.

### BACKGROUND

Integrated circuit “dies” or “dice” are small cubes of semiconductor material such as silicon that have various interconnected electrical circuits formed therein. Each die typically has a metalized surface layer with electrical contact regions thereon that allows the die to be connected to other electronic components. Integrated circuit dice are produced by “singulating” (“dicing”) a unitary semiconductor wafer having identical circuits formed in adjacent regions thereof that are arranged in a rectangular generally waffle-shaped grid. Saw cuts or laser fractures are made along “saw streets” to cut the wafer into dice. A diced wafer is often supported on a deformable sheet known as dicing tape. The dicing tape may be stretched by force applied to its outer perimeter. Stretching the dicing tape causes the diced wafer supported on it to expand laterally, thereby separating the dice. The separated dice may then be picked up, one at a time, by pick and place machines or the like. With very small dice, i.e., less than about 1.0 mm, current methods of expanding the dicing tape tend to provide insufficient space between dice, or the space provided shrinks sufficiently after initial expansion, such that handling of the dice is difficult and often ends with damage to adjacent dice.

### BRIEF DESCRIPTION OF THE DRAWINGS

FIG. 1 is a schematic cross sectional elevation view of a wafer processing table with a singulated wafer mounted thereon.

FIG. 2 is a top plan view of the wafer processing table of FIG. 1 in a closed position.

FIG. 2A is a cross sectional elevation view of the wafer processing table of FIG. 1 in a closed position.

FIG. 3 is a top plan view of the wafer processing table of FIG. 1 in an open position.

FIG. 3A is a cross sectional elevation view of the wafer processing table of FIG. 1 in an open position.

FIG. 4 is a top plan view of a top outer annular portion of the wafer processing table of FIG. 1 showing expansion joints thereof.

FIG. 5 is a detail schematic isometric view of a table expansion joint.

FIG. 6 is a cross sectional elevation view of a singulated wafer mounted on dicing tape that is attached to a first wafer frame ring.

FIG. 6A is a top isometric view of the singulated wafer, dicing tape and first wafer frame ring of FIG. 6.

FIG. 7 is a cross sectional elevation view of the singulated wafer, dicing tape and first wafer frame ring of FIG. 6 supported on a wafer processing table with the wafer in a first expanded state and with the table in a raised and closed position.

FIG. 8 is a schematic cross sectional elevation view that is the same as FIG. 7, except with a second wafer frame ring attached to the dicing tape.

FIG. 9 is a schematic cross sectional elevation view showing the wafer in a second expanded state with the processing table positioned in an expanded position.

FIG. 10 is a cross sectional elevation view substantially identical to FIG. 9 except with a tape press roller pressing the second wafer frame ring against the dicing tape.

FIG. 10A is a detail cross sectional view of a tape press roller pressing the second wafer frame ring into engagement with dicing tape supported on the wafer processing table.

FIG. 11 is a cross sectional elevation view with the wafer processing table in a closed and lowered position and disengaged from the dicing tape.

FIG. 12 is a cross sectional elevation view of an expanded wafer, dicing tape and first and second wafer frame rings showing an annular cut being made to the dicing tape.

FIG. 13 is a cross sectional elevation view of the expanded wafer of FIG. 12 with a cutaway portion of the dicing tape and the first wafer frame ring being removed.

FIG. 14 is a cross sectional elevation view of an expanded wafer supported on trimmed dicing tape attached to the second wafer frame ring.

FIG. 14A is a top isometric view of the expanded wafer, dicing tape and second support ring of FIG. 14.

FIG. 15 is a flow diagram of one embodiment of a method of separating dies of a singulated wafer.

FIG. 16 is a flow diagram of another embodiment of a method of separating dies of a singulated wafer.

### DETAILED DESCRIPTION

As used herein, terms such as lateral, horizontal, longitudinal, vertical and similar terms do not imply an orientation within a gravitational field. Rather, these terms are used in a relative sense for providing a frame of reference to describe the spacial relationships of various portions of physical assemblies such as a wafer processing table 10. Terms such as up, down, above, below, sideways, etc., are used in this same relative sense.

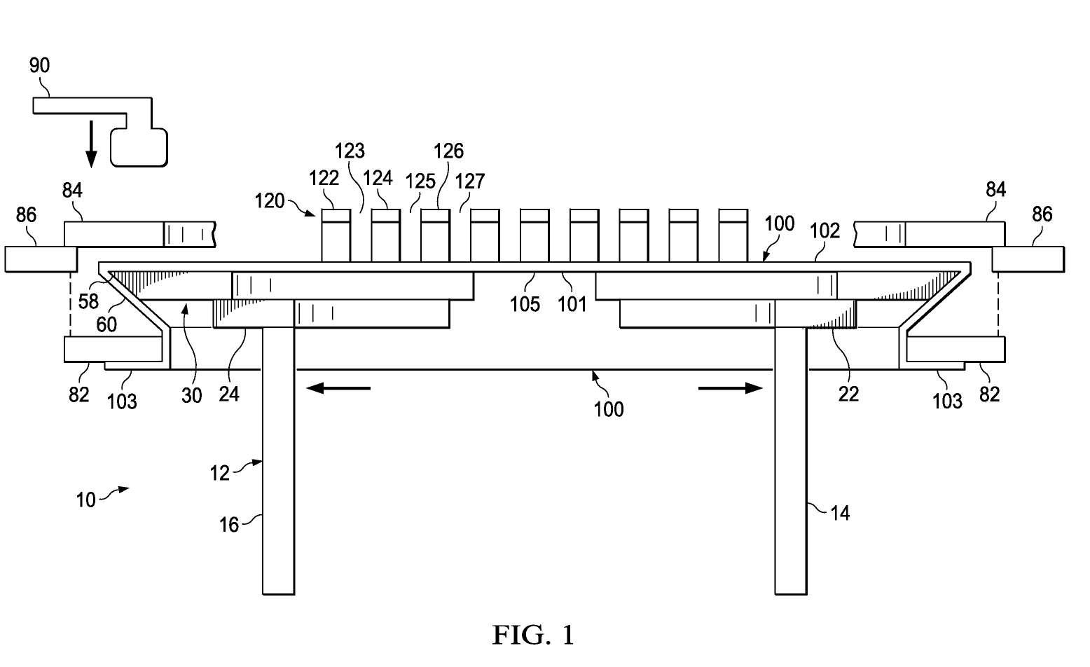

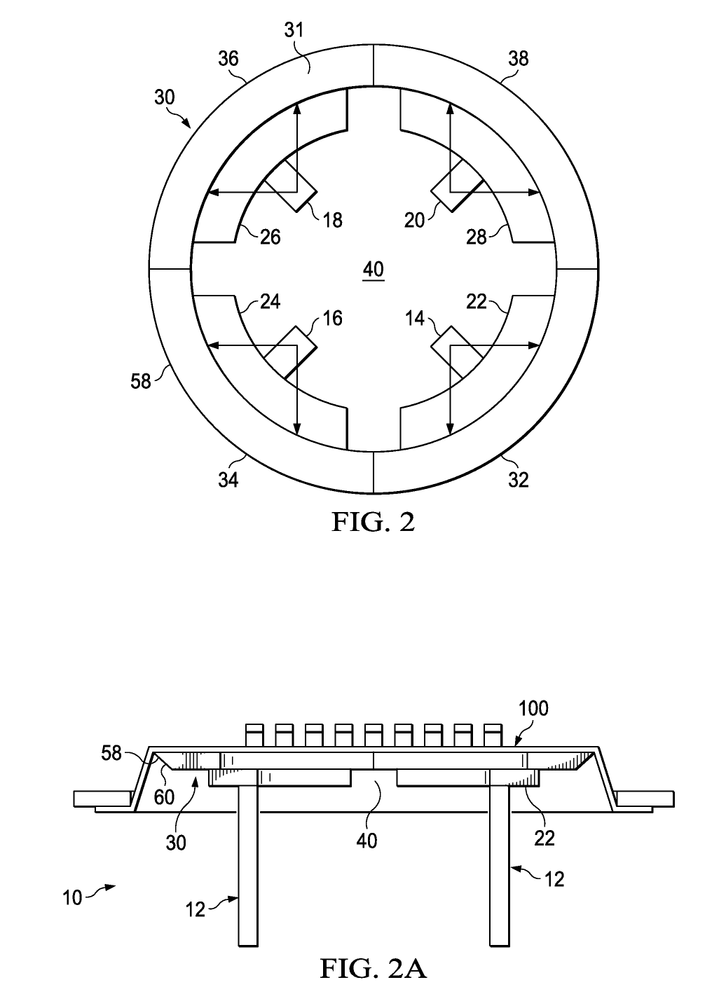

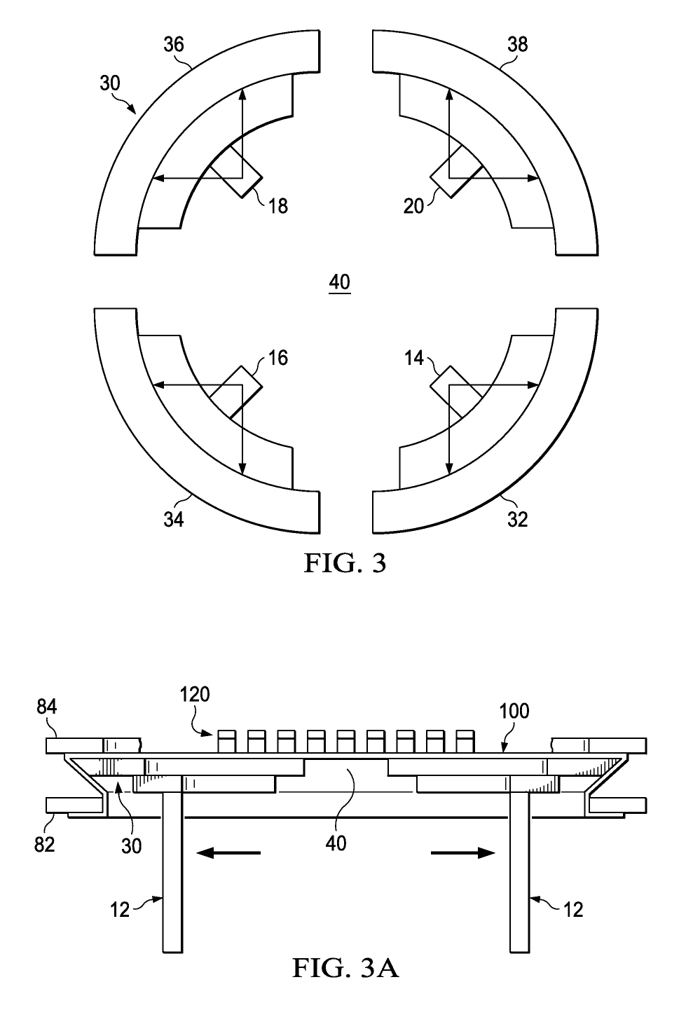

FIGS. 1-3A illustrate a wafer processing table 10 having a table base 12 that may include a plurality of legs 14, 16, 18, 20. Each leg is attached to a corresponding horizontally disposed arcuate portion 22, 24, 26, 28. The table base 12 supports a table top or table head 30 comprising a top surface 31 and a plurality of arcuate, horizontally disposed sections 32, 34, 36, 38 which are attached to corresponding ones of the horizontally disposed, arcuate base portions 22, 24, 26, 28. The table is horizontally displaceable between a closed position as shown in FIGS. 2 and 2A, and an expanded position as shown in FIGS. 1, 3 and 3A. The table 10 is also displaceable between a raised position and a lowered position as further described below. The table top 30 may comprise a central opening 40 which becomes larger when the table moves from the closed position of FIGS. 2 and 2A to the expanded position of FIGS. 3 and 3A. It should be noted that the drawings are schematic and not to scale.

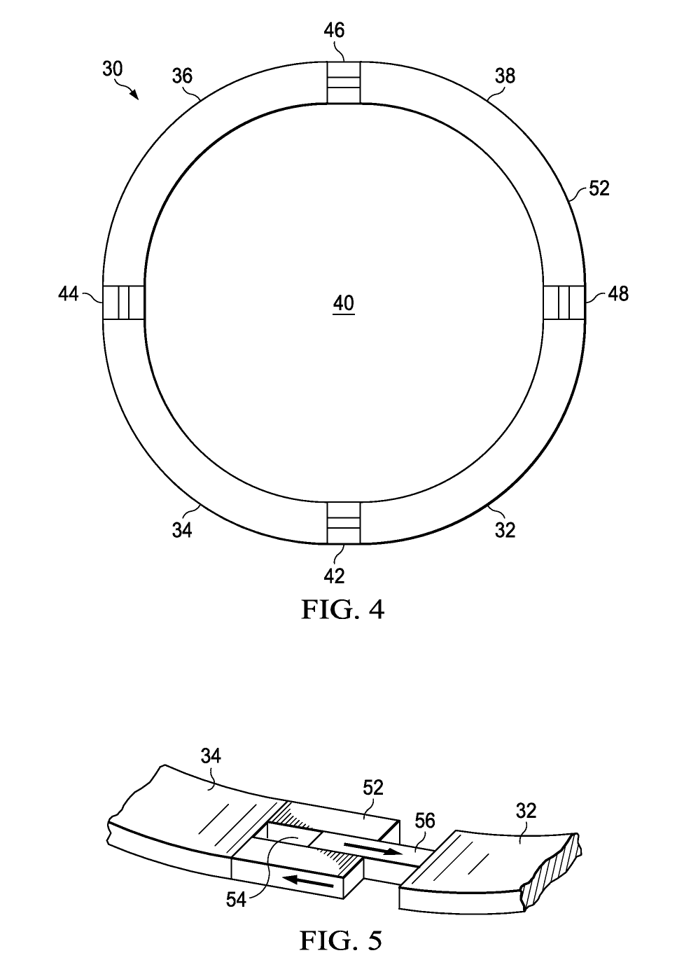

As illustrated in FIGS. 4 and 5, each table top arcuate portion 32, 34, 36, 38 may be connected to the two adjacent arcuate portions by expandable joints 42, 44, 46, 48. In one embodiment, the expandable joints each comprise a first member 52 attached to an end of one arcuate section, e.g., 34. The first member 52 may comprise a central opening/channel portion 54 that is adapted to slidingly receive a second member 56, which is attached to an adjacent arcuate section, e.g., section 32. It will be understood that FIG. 5 is merely a schematic representation of an expansion joint and many other expansion joint configurations could also be used. The table top arcuate horizontally disposed sections 32, 34, 36, 38 terminate at an outer periphery 58 having a downwardly and inwardly sloping nose portion 60 as illustrated in FIGS. 1--2A.

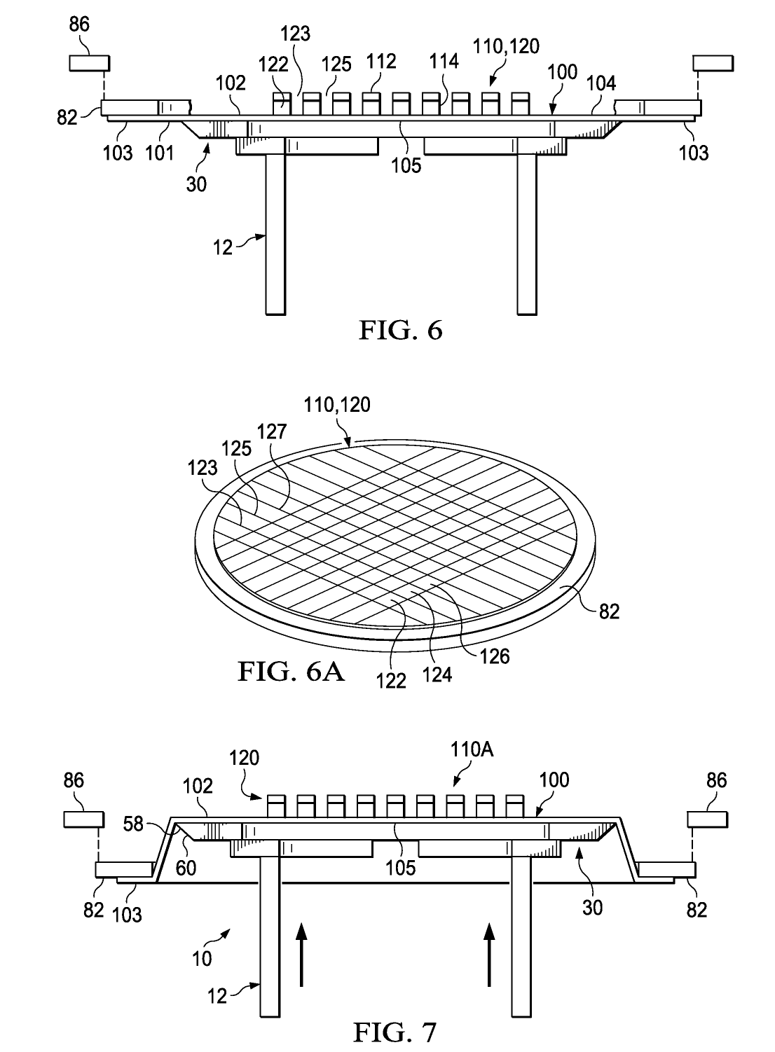

As best shown in FIG. 1, dicing tape 100, which may be made from polyvinyl chloride, is deformable under pressure. The dicing tape 100 has a non- tacky or smooth surface 101 and an opposite tacky surface 102. The dicing tape 100 may be provided as a generally circular sheet having an outer circumferential portion 103 that is attached by its tacky surface 102 to the first wafer frame ring 82 when the dicing tape is in a taught but relatively unstretched state as shown in FIGS. 6 and 6A.

Initially, as shown in FIGS. 6 and 6A, a “singulated” (“diced”) wafer 110 may have a generally circular shape and may comprise an upper metalized circuit layer 112 and a lower silicon layer 114. The singulated wafer 110 shown in FIGS. 6 and 6A has been singulated into a plurality of dies 120 by a plurality of linear saw cuts or laser fractures 123, 125, 127, etc., which divide the wafer 110 into a plurality of individual, closely spaced dies or dice 122, 124 ,126. Typical wafer diameters are 8 inches and 12 inches.

As illustrated by FIGS. 6 and 6A, a singulated but unexpanded wafer 110 is initially placed at a center portion 105 of the dicing tape 100 with the bottom surface of the silicon layer 114 attached to the tacky side 102 of the dicing tape 100. A first wafer frame ring 82 (also referred to herein as a “frame ring” or simply a “ring”) is also attached, at the bottom surface thereof, to the tacky top surface 102 of the dicing tape peripheral portion 103. The first frame ring 82 may be pressed into engagement with the dicing tape 100 with a roller or by other means to secure it to the dicing tape outer peripheral portion 103.

As illustrated in FIG. 7, the dicing tape 100, wafer 110 and support ring 82 assembly of FIGS. 6 and 6A may be placed on a wafer processing table 10 such as described above with reference to FIGS. 1-3A. The first frame ring 82 may have an outer edge portion removably mounted in notch portions (not shown) of a plurality of frame ring support members 86 arranged around the periphery or ring 82. A typical frame ring for an 8 inch wafer may have an inner diameter of 250 mm and an outer diameter of 296 mm. A 12 inch diameter wafer may have a frame ring with an inner diameter of 350 mm and an outer diameter of 400 mm. In FIG. 7, the table 12 has been raised relative to the frame ring 82 and frame ring support member 86. (In another embodiment the frame ring 82 and support member 86 are moved downward relative to a stationary table.) Thus, in FIG. 7, the frame ring 82 is positioned below and radially outwardly of outer perimeter 58 of the table top 30. Raising the table top 30 has also caused the dicing tape 100 to expand radially, thus placing the singulated wafer 110 in a first expanded position 110A, as shown in FIGS. 1, 7 and 8.

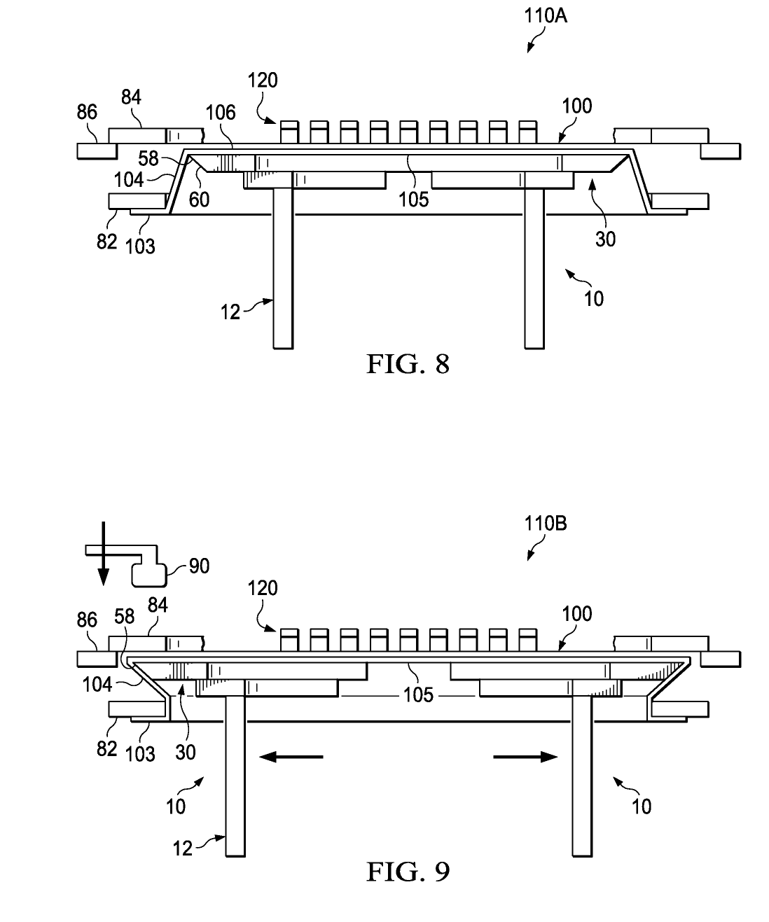

As illustrated in FIG. 8, a second frame ring 84 is now removably mounted on the frame ring annular support members 86 at a position directly above the first frame ring 82. The second frame ring 84 in this position is located slightly above and slightly radially outwardly periphery 58 of the upper surface of table top 30.

Next, with the table 12 still in the raised position, the table is moved to the laterally expanded position shown in FIG. 9. In this expanded position, the dicing tape 100 is further stretched, thereby placing the wafer 110B in a further radially expanded state. The middle portions of frame ring 82 is now positioned below and the middle portion of frame ring 84 is positioned above the table top outer periphery 58. A tape press roller assembly 90 is positioned directly above the second frame ring 84.

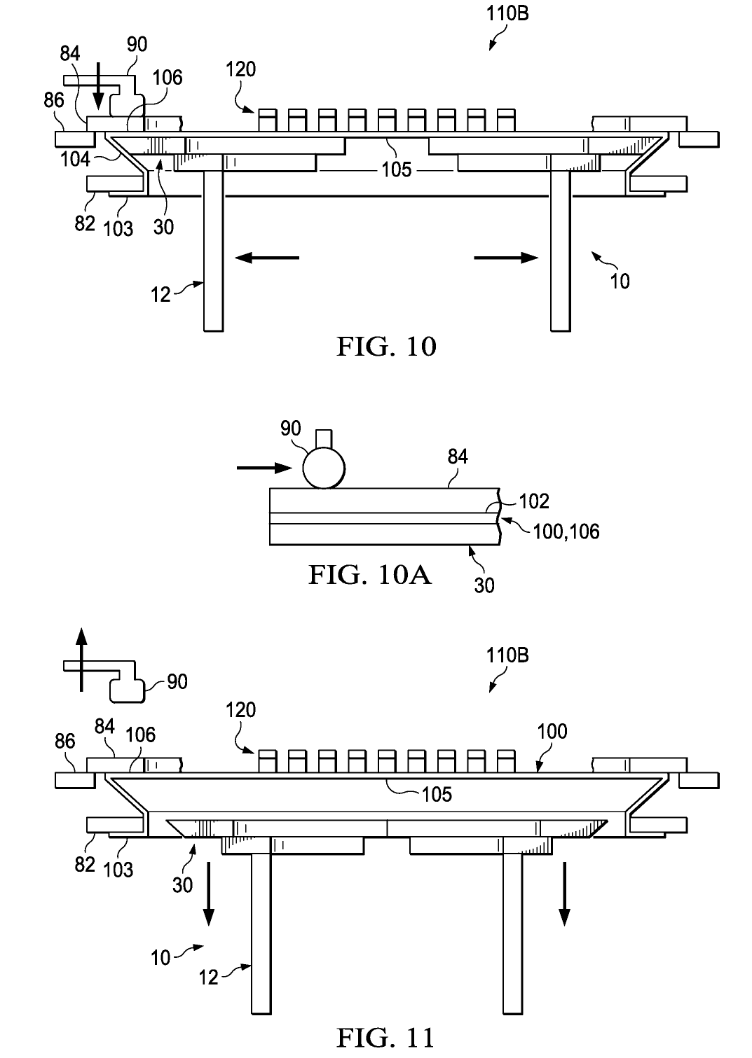

Next, as illustrated in FIGS. 10 and 10A, the tape press roller assembly 90 is moved downwardly into engagement with the second frame ring 84 and is moved in a circle around the ring 84, pressing it downwardly into engagement with an annular portion 106 of the dicing tape 100 which is supported by table top 30. This process causes the second ring 84 to be fixedly attached to the annular portion 106 through the action of the tacky top surface 102 of the dicing tape 100. Thus, the second die frame ring 84 is now attached to an annular portion 106 of the dicing tape 100. Annular portion 106 is thus positioned radially outwardly of the circular portion 105 that supports the expanded wafer 110B/plurality of dice 120.

As illustrated in FIG. 11, the tape press roller assembly 90 is now moved upwardly, out of engagement with the second ring 84, and the table 12 is now moved to a smaller diameter, laterally closed position. The table top 30 is also moved to a lowered position with respect to the dicing tape 100, frame rings 82, 84 and frame ring support member 86.

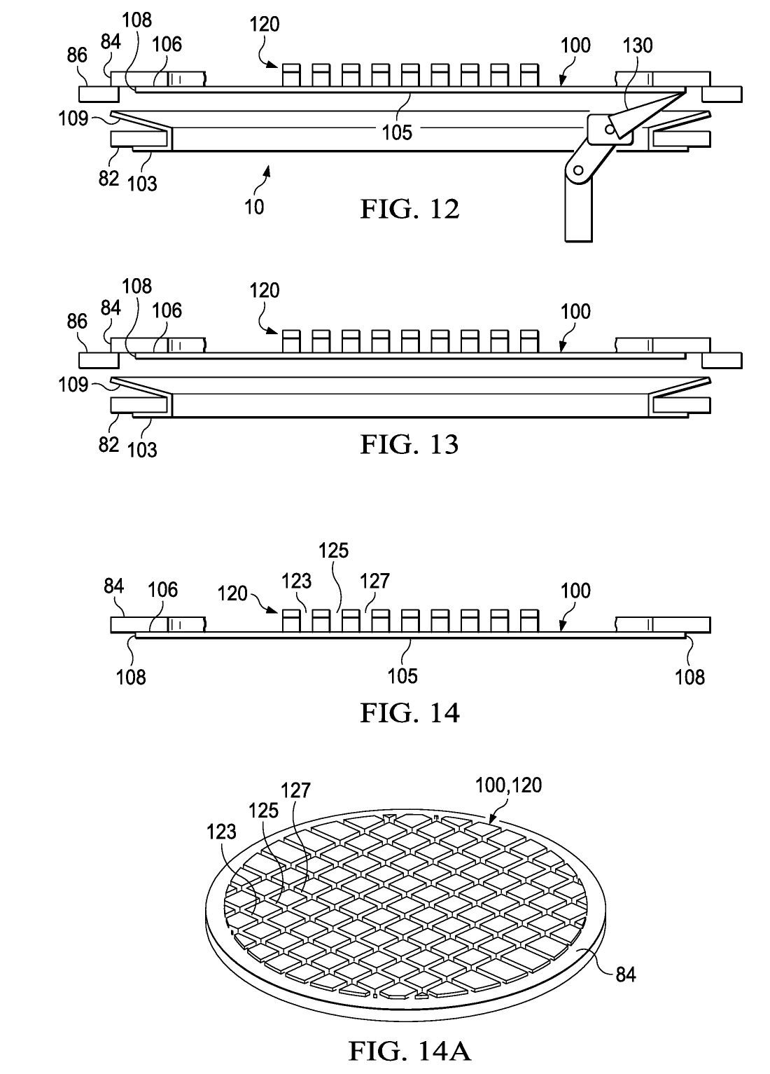

Next, as illustrated in FIG. 12, a cutter 130 makes a circular cut in the dicing tape 100 at a position that may be near the center of the second ring 84, thus providing the dicing tape 100 with a new circular outer periphery 108.

Next, as illustrated in FIG. 13, the first frame ring 82 and a cutaway portion 109 of the dicing tape 100 are entirely separated from the remainder of the dicing tape 100 and second frame ring 84. Thus, as illustrated in FIGS. 14 and 14B, an assembly is provided having a plurality of spaced apart dice 120 mounted on a dicing tape 100 that is attached at its peripheral edge 108 to a second frame ring 84 that in one embodiment has the same size and diameter as the first frame ring 82. The expanded wafer 110B in this second expanded state of the dicing tape 100 (the state provided after the second expansion operation of FIG. 9) provides ample room, e.g. 0.01 mm, between dice 120 to enable handling thereof by a pick and place machine or the like without damaging the dice 120. In this second expanded state, the dice 120 are also positioned sufficiently far apart that even with minor inward “creep” (radially inward contraction) of the dicing tape 100 over time, there will remain sufficient space between the dice 120 for proper handling without damage to the dice 120.

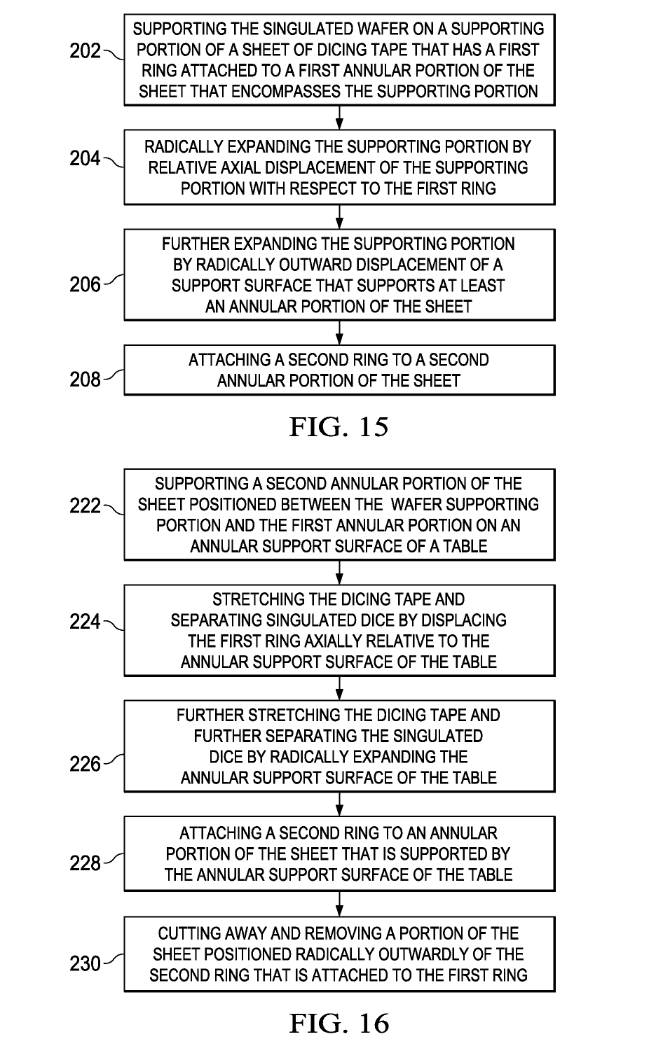

It will be appreciated from the above description that a method of separating dice 120 of a singulated wafer 110 may comprise, as illustrated by FIG. 15, may comprise supporting the singulated wafer 110 on a supporting portion 105 of a sheet 100 of dicing tape that has a first ring 82 attached to a first annular portion 103 of the sheet 100 that encompasses the supporting portion 105, as shown at block 202 and FIG. 6. The method may include, as shown at block 204 and FIG. 7, radially expanding the supporting portion 105 by relative axial (upward) displacement of the supporting portion 105 with respect to the first ring 82. The method may also include, as shown at block 206 and FIG. 9, further expanding the supporting portion by radially outward displacement of a support surface 31 that supports at least an annular portion 106 of the sheet. The method may further include, as shown at block 20 and FIG. 10, attaching a second ring 84 to a second annular portion 106 of the sheet.

It will also be appreciated that a method of separating dies 120 of a singulated wafer 110 supported on a wafer supporting portion 105 of a sheet 100 of dicing tape having a first ring 82 attached to a first annular portion 103 of the sheet 100 that encompasses the supporting portion 105 may comprise, as shown in FIG. 16, supporting a second annular portion 104 of the sheet 100 positioned between the wafer supporting portion 105 and the first annular portion 103 on an annular support surface 31 of a table 10, as shown in block 222 and FIG. 6. The method may also include, as shown at block 224 and FIG. 7, stretching the dicing tape 100 and separating singulated dice 120 by displacing the first ring 82 axially relative to the annular support surface 31 of the table 10. The method may include, as illustrated at block 226 and FIG. 9, further stretching the dicing tape 100 and further separating the dice 120. The method may also include, as shown at block 228 and FIG. 10, attaching a second ring 84 to an annular portion 106 of the dicing tape 10 that is supported by the annular support surface 31 of the table; and, as shown at 230 and FIGS. 11-14, cutting away and removing a portion 109 of the sheet 10 positioned radially outwardly of the second ring 84.

Certain embodiments of methods of separating singulated dies have been expressly described herein. It will be understood by those skilled in the art after reading this disclosure, that the methods and apparatus expressly described herein could be variously otherwise embodied. It is intended that the appended claims be broadly construed so as to cover such alternative embodiments, except as limited by the prior art.

What is claimed is:

1. A method of separating dies of a singulated wafer comprising:
supporting the singulated wafer on a supporting portion of a sheet of dicing tape that has a first ring attached to a first annular portion of the sheet that encompasses the supporting portion;
radially expanding the supporting portion by relative axial displacement of the supporting portion with respect to the first ring;
further expanding the supporting portion by radially outward displacement of a support surface that supports at least an annular portion of the sheet; and
attaching a second ring to a second annular portion of the sheet.

2. The method of claim 1 further comprising making an annular cut in the sheet between the first ring and the second ring.

3. The method of claim 2 wherein said making an annular cut comprises making an annular cut in the sheet proximate to the outer periphery of the second ring.

4. The method of claim 1 wherein said supporting comprises supporting the singulated wafer on a tacky side of the sheet of dicing tape.

5. The method of claim 4 wherein said attaching a first ring comprises attaching the first ring to the tacky side of the dicing tape.

6. The method of claim 4 wherein said attaching a second ring comprises attaching the second ring to the tacky side of the dicing tape.

7. The method of claim 1 wherein said radially expanding the supporting portion by relative axial displacement of the supporting portion with respect to the first ring comprises axially displacing the support surface relative to the first ring.

8. The method of claim 1 wherein said further expanding the supporting portion by radially outward displacement of the support surface comprises radially displacing the support surface relative to the first ring.

9. The method of claim 1 wherein said attaching a second ring to a second annular surface portion of the sheet comprises positioning the second ring over an annular portion of the sheet that is supported by the support surface.

10. The method of claim 10 wherein said attaching a second ring further comprises applying axial force to the second ring with a roller.

11. The method of claim 1 wherein said attaching a second ring to a second annular portion of the sheet comprises attaching a second ring the same size as the first ring.

12. A method of separating dies of a singulated wafer supported on a wafer supporting portion of a sheet of dicing tape having a first ring attached to a first annular portion of the sheet that encompasses the supporting portion comprising:
supporting a second annular portion of the sheet positioned between the wafer supporting portion and the first annular portion on an annular support surface of a table;
stretching the dicing tape and separating singulated dice by displacing the first ring axially relative to the annular support surface of the table;
further stretching the dicing tape and further separating the singulated dice by radially expanding the annular support surface of the table;
attaching a second ring to an annular portion of the sheet that is supported by the annular support surface of the table; and
cutting away and removing a portion of the sheet positioned radially outwardly of the second ring.

13. An assembly comprising:
a sheet of dicing tape having a smooth side and a tacky side;
a wafer singulated into a plurality of dies attached to said tacky side of the dicing tape and positioned within a first region thereof;
a first ring attached to said dicing tape at a first annular portion thereof positioned outwardly of said first region; and
a dicing tape support table having an annular tape support surface and having a first operating position wherein said annular support surface has a relatively small diameter and a second operating position wherein said annular support surface has a relatively large diameter; wherein said sheet of dicing tape is supported on said annular tape support surface.

14. The assembly of claim 13 wherein said first ring is positioned below said annular tape support surface.

15. The assembly of claim 14 further comprising a second ring positioned on said dicing tape at a second annular portion thereof.

16. The assembly of claim 15 wherein said dicing tape support table is in said first operating state and said second ring is positioned above and radially outwardly of said annular tape support surface.

17. The assembly of claim 15 wherein said dicing tape support table is in said second operating position and said second ring is positioned directly above and at least a portion of said annular tape support surface.

18. The assembly of claim 17 wherein said second ring is positioned on said tacky side of said dicing tape and further comprising a roller engaging said second ring that urges it against said dicing tape.

19. The assembly of claim 13 wherein dicing tape support table is in said second operating position and wherein said second ring is positioned above and radially outward of the tape support surface and further comprising a cutting assembly cuttingly engaging said dicing tape at a position proximate said second ring.

20. The assembly of claim 19 wherein said dicing tape is comprises a circular portion supporting said singulated dies and terminating at said second ring and an annular portion attached to said first ring and separated from said circular portion.
